(19) United States
(12) Patent Application Publication
(10) Pub. No.: US 2025/0199526 A1
(43) Pub. Date: Jun. 19, 2025

(54) CONTROL METHOD OF SUBSTRATE PROCESSING APPARATUS

(71) Applicant: Tokyo Electron Limited, Tokyo (JP)

(72) Inventor: Hiroichi OTA, Iwate (JP)

(21) Appl. No.: 18/975,358

(22) Filed: Dec. 10, 2024

(30) Foreign Application Priority Data
Dec. 18, 2023 (JP) 2023-213205

(51) Int. Cl. G05B 23/02

(52) U.S. Cl. CPC G05B 23/0294

(57) ABSTRACT

A method of controlling a substrate processing apparatus includes: when an abort occurs in a substrate processing apparatus during a film forming processing on a substrate using a process recipe, generating an additional process recipe for the film forming processing according to a timing of the abort; and performing an additional film forming processing on the substrate according to the additional process recipe.

### CROSS-REFERENCE TO RELATED APPLICATIONS

This application is based on and claims priority from Japanese Patent Application No. 2023-213205 filed on Dec. 18, 2023 with the Japan Patent Office, the disclosure of which is incorporated herein in its entirety by reference.

### TECHNICAL FIELD

The present disclosure relates to a control method of a substrate processing apparatus.

### BACKGROUND

Japanese Patent Application Laid-Open No. 2018-019095 discloses a substrate processing method in which a substrate processing is aborted when an abnormality occurs in a substrate processing apparatus during a period from the start of a preliminary processing and before the start of the substrate processing. When the abnormality is resolved, the disclosed processing method resumes a post-abnormality preliminary processing and the substrate processing apparatus in this order. Also, Japanese Patent Application Laid-Open No. 2014-064020 discloses a substrate processing apparatus that performs a substrate processing according to a processing recipe.

### SUMMARY

According to one aspect, a method of controlling a substrate processing apparatus, includes: when an abort occurs in a substrate processing apparatus during a film forming processing on a substrate using a process recipe; generating an additional process recipe for the film forming processing according to a timing of the abort; and performing an additional film forming processing on the substrate according to the additional process recipe.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating an example of the configuration of a substrate processing system.

FIG. 2 is a flow chart illustrating an example of a substrate processing method.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment for carrying out the present disclosure will be described with reference to drawings. In the drawings, the same components may be given the same reference numerals, and redundant descriptions thereof may be omitted in some cases.

[Substrate Processing System]

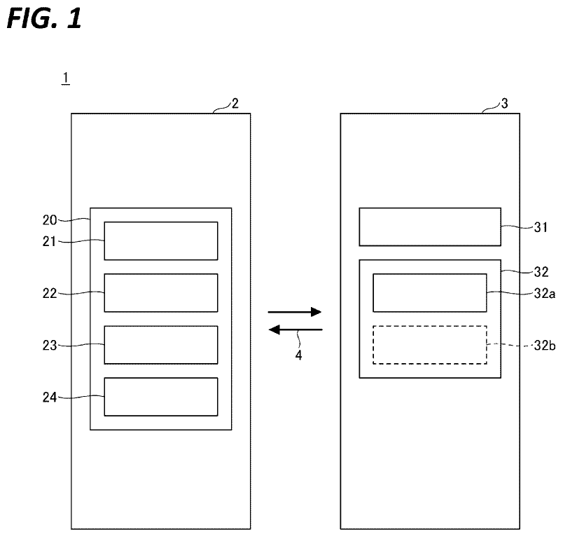

First, an example of the configuration of a substrate processing system 1 according to the present embodiment will be described with reference to FIG. 1. FIG. 1 is a schematic view illustrating an example of the configuration of the substrate processing system 1.

The substrate processing system 1 includes a substrate processing apparatus 2 and an optimization apparatus 3.

The substrate processing apparatus 2 is an apparatus that performs a desired processing (e.g., a film forming processing) on a substrate. The following descriptions will be made on an example of a case where the substrate processing apparatus 2 is a film forming apparatus that performs a desired film forming processing on a substrate. The substrate processing apparatus 2 may be, for example, a film forming apparatus that supplies a processing gas into a processing container, and performs desired film forming processing on a substrate. The processing container accommodates a substrate support that supports the substrate. Specifically, the substrate processing apparatus 2 may be a chemical vapor deposition (CVD) apparatus or an atomic layer deposition (ALD) apparatus. Also, the substrate processing apparatus 2 may be, for example, a film forming apparatus that generates plasma of a processing gas within a processing container, and performs desired film forming processing on a substrate. Specifically, the substrate processing apparatus 2 may be a plasma-enhanced chemical vapor deposition (PE-CVD) apparatus or a plasma-enhanced atomic layer deposition (PE-ALD) apparatus. Also, the substrate processing apparatus 2 may be, for example, a film forming apparatus that causes sputtering for a target provided in a processing container, and performs desired film forming processing on a substrate. Specifically, the substrate processing apparatus 2 may be a physical vapor deposition (PVD) apparatus. The deposition method of the substrate processing apparatus 2 is not limited to these. The substrate processing apparatus 2 includes a control device 20. The control device 20 is, for example, a computer, and includes, for example, a central processing unit (CPU), a random access memory (RAM), a read only memory (ROM), and an auxiliary storage device. The CPU operates based on a program stored in the ROM or the auxiliary storage device, and controls the operation of the substrate processing apparatus 2.

The optimization apparatus 3 is, for example, a computer, and includes, for example, a central processing unit (CPU), a random access memory (RAM), a read only memory (ROM), and an auxiliary storage device. The CPU operates based on a program stored in the ROM or the auxiliary storage device, and generates recipes for the substrate processing apparatus 2 (a process recipe 32a, and an additional film formation recipe 32b).

The optimization apparatus 3 is connected to the control device 20 of the substrate processing apparatus 2 via a wired or wireless communication unit 4. For example, the optimization apparatus 3 transmits recipes (the process recipe 32a, and the additional film formation recipe 32b) to the control device 20 of the substrate processing apparatus 2 via the communication unit 4. The control device 20 of the substrate processing apparatus 2 controls the operation of the substrate processing apparatus 2 based on the recipes, so that desired processing is performed on a substrate.

The control device 20 of the substrate processing apparatus 2 includes a control unit 21, an abort determination unit 22, an input unit 23, and an output unit 24.

The control unit 21 controls the substrate processing apparatus 2 according to the recipes (the process recipe 32a, and the additional film formation recipe 32b). Accordingly, a desired film is formed on the substrate.

The abort determination unit 22 determines whether an abort has occurred during the recipe, in the substrate processing apparatus 2 controlled according to the recipe.

The configuration of the input unit 23 allows an operator to input operations. The input unit 23 may be, for example, an input device that may be operated by the operator.

The output unit 24 outputs, for example, various information. The output unit 24 may be, for example, a display device that visually displays various information.

The optimization apparatus 3 includes an additional film formation recipe generation unit 31 and a storage unit 32.

The additional film formation recipe generation unit 31 generates the additional film formation recipe 32b. The generation of the additional film formation recipe 32b will be described below.

The storage unit 32 stores the process recipe 32a for performing substrate processing. Also, the storage unit 32 stores the additional film formation recipe 32b generated by the additional film formation recipe generation unit 31. Also, the storage unit 32 stores, for example, logs of the substrate processing apparatus 2 output from the control device 20 via the communication unit 4.

Next, an example of the operation of the optimization apparatus 3 will be described. In the process recipe 32a, conditions required for substrate processing (e.g., control values of temperature, gas flow rate, pressure, time, etc.) are set in advance. The control unit 21 controls the substrate processing apparatus 2 according to the process recipe 32a. Accordingly, a desired film is formed on the substrate.

Meanwhile, when the substrate processing apparatus 2 performs film forming processing on the substrate, the process recipe may be interrupted (aborted) for various reasons (e.g., sensor value abnormality, time-out, etc.). A substrate for which the abort processing of the process recipe has been executed after the start of the film forming processing is judged to be a substrate in a state where it is unclear whether the film forming processing has been completed (hereinafter, also referred to as a gray state). The substrate determined to be in a gray state cannot be sent to a process subsequent to a film forming process.

Here, for the substrate determined to be in a gray state, the surface state of the substrate is measured, and a decision is made as to whether to discard the substrate or to perform recovery processing. Furthermore, for the substrate determined to be subjected to the recovery processing, a decision is made as to whether to etch the substrate surface and perform the film forming processing again from the beginning, or to perform additional film forming processing on the substrate. Then, the determined processing is performed on the substrate.

Also, when the substrate is determined to be additionally subjected to the film forming processing, it is necessary to generate an additional film formation recipe according to the occurrence timing of the abort processing. Simply adjusting only the film forming time or executing the rest of the process recipe after the abort occurrence is not sufficient for the generation of the additional film formation recipe. For example, it is required to consider changing a gas to be flowed (e.g., a change from a film forming gas to an inert gas (N₂ gas)) so that the temperature before the abort occurrence is reset and then the rest of the process recipe after the abort occurrence is executed. In particular, such consideration is necessary in the process recipe in which the film formation is performed while the temperature is raised or lowered. For this reason, the generation of the additional film formation recipe is difficult for anyone other than engineers with a lot of experiences.

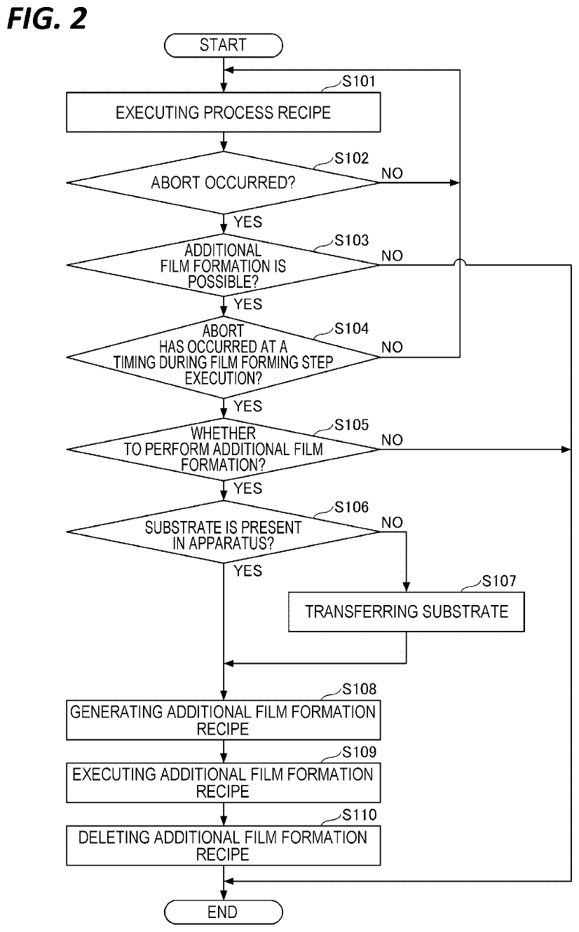

Next, the control method of the substrate processing apparatus 2 according to the present embodiment will be described by using FIG. 2.

In the step S101, the process recipe 32a is executed. Here, the process recipe 32a is transmitted from the optimization apparatus 3 to the control device 20, and then is stored in the ROM or the auxiliary storage device of the control device 20. The control unit 21 controls the substrate processing apparatus 2 according to the process recipe 32a stored in the ROM or the auxiliary storage device of the control device 20.

In the step S102, it is determined whether an abort has occurred. Here, the abort determination unit 22 determines whether an abort has occurred in the substrate processing apparatus 2. When no abort has occurred (S102; NO), the processing of the control device 20 returns to the step S101, and the control of the substrate processing apparatus 2 is continued based on the process recipe 32a. When the process recipe 32a is ended without the abort occurrence and a desired film is formed on the substrate, the processing of the control device 20 illustrated in FIG. 2 is ended.

When an abort has occurred (S102; YES), the processing of the control device 20 proceeds to the step S103. When an abort has occurred, for example, a warning display may be displayed on the output unit 24, in another configuration.

In the step S103, it is determined whether additional film formation is possible on the substrate. Here, the operator checks the state of the substrate surface (e.g., the state of particles attached to the substrate surface). Also, the operator checks the presence/absence of abnormality in the substrate processing apparatus 2 or the presence/absence of abnormality on the substrate. Then, whether the additional film formation is possible on the substrate is input by the operator to the control device 20 via the input unit 23, and is transmitted from the control device 20 to the optimization apparatus 3 via the communication unit 4. Based on input results of the operator, the optimization apparatus 3 determines whether the additional film formation is possible on the substrate. When it is determined that the additional film formation is impossible (S103; NO), the processing of the optimization apparatus 3 is ended. That is, this substrate is discarded.

When it is determined that the additional film formation is possible (S103; YES), the processing of the optimization apparatus 3 proceeds to the step S104.

In the step S104, it is determined whether the abort has occurred at a timing during the execution of a film forming step. The optimization apparatus 3 determines whether the abort has occurred at a timing during the execution of the film forming step, based on logs of the substrate processing apparatus 2 stored in the storage unit 32. Here, the process recipe 32a includes the film forming step of forming a desired film on the substrate, a pre-treatment step to be performed before the film forming step, and a post-treatment step to be performed after the film forming step. When the abort occurrence timing is not during the execution of the film forming step (S104; NO), the processing of the optimization apparatus 3 returns to the step S101. Here, when the abort has occurred in the pre-treatment step before the execution of the film forming step, the process recipe 32a is executed again (S101). When the abort has occurred in the post-treatment step after the execution of the film forming step, the processing of the optimization apparatus 3 illustrated in FIG. 2 is ended.

When the abort has occurred at a timing during the execution of the film forming step (S104; YES), the processing of the optimization apparatus 3 proceeds to the step S105.

In the step S105, it is determined whether to perform the additional film formation on the substrate. Here, whether to perform the additional film formation is input by the operator to the control device 20 via the input unit 23, and is transmitted from the control device 20 to the optimization apparatus 3 via the communication unit 4. Based on input results of the operator, the optimization apparatus 3 determines whether to perform the additional film formation on the substrate. When it is determined not to perform the additional film formation (S105; NO), the processing of the optimization apparatus 3 is ended. That is, this substrate is discarded.

When it is determined to perform the additional film formation (S105; YES), the processing of the optimization apparatus 3 proceeds to the step S106.

In the step S106, it is determined whether the substrate is present in the substrate processing apparatus 2. The optimization apparatus 3 determines whether the substrate is present within the substrate processing apparatus 2, based on state information of a substrate transport device (not illustrated). When the substrate is present in the substrate processing apparatus 2 (S106; YES), the processing of the optimization apparatus 3 proceeds to the step S108. When no substrate is present in the substrate processing apparatus 2 (S106; NO), the processing of the optimization apparatus 3 proceeds to the step S107.

In the step S107, the optimization apparatus 3 controls the substrate transport device (not illustrated) to transport the substrate into the substrate processing apparatus 2. Then, the processing of the optimization apparatus 3 proceeds to the step S108.

In the step S108, the additional film formation recipe 32b is generated. Here, the additional film formation recipe generation unit 31 automatically generates the additional film formation recipe 32b according to the abort occurrence timing, and stores the additional film formation recipe 32b in the storage unit 32.

First, the additional film formation recipe generation unit 31 determines how far the film forming step has progressed when the abort has occurred, depending on the abort occurrence timing. Specifically, the additional film formation recipe generation unit 31 determines how far the film forming step of the process recipe 32a has progressed when the abort has occurred, by using at least one of the logs of the substrate processing apparatus 2 stored in the storage unit 32, the measurement results of various measuring instruments (actual sensors) in the substrate processing apparatus 2, the measurement results of the virtual metrology (virtual sensors) in the substrate processing apparatus 2, and the measurement data of the substrate surface (e.g., measurement data of the substrate surface in the step S103). The logs of the substrate processing apparatus 2 stored in the storage unit 32 include, for example, the abort timing, the temperature, the process gas flow rate, the progress of the film forming step, and the time during which the step was executed. The measurement data detected by the actual sensors in the substrate processing apparatus 2 includes, for example, the film thickness information, the pressure, and the temperature. The measurement data detected by the virtual sensors in the substrate processing apparatus 2 includes, for example, the virtual film thickness, and the virtual temperature. The measurement data of the substrate surface includes, for example, the film thickness information, the surface roughness, the number of particles on the substrate surface.

Then, based on the determination result of how far the film forming step has progressed when the abort has occurred, the additional film formation recipe generation unit 31 automatically generates the additional film formation recipe 32b, and stores the additional film formation recipe 32b in the storage unit 32.

In the step S109, the additional film formation recipe 32b is executed. Here, the additional film formation recipe 32b is transmitted from the optimization apparatus 3 to the control device 20, and is stored in the ROM or the auxiliary storage device of the control device 20. The control unit 21 controls the substrate processing apparatus 2 according to the additional film formation recipe 32b stored in the ROM or the auxiliary storage device of the control device 20.

In the step S110, the additional film formation recipe 32b is deleted. Here, the control device 20 deletes the additional film formation recipe 32b stored in the ROM or the auxiliary storage device. Also, the optimization apparatus 3 deletes the additional film formation recipe 32b from the storage unit 32.

As described above, according to the control method of the substrate processing apparatus 2 according to the present embodiment, when the operator gives an instruction (S105; YES), the additional film formation recipe 32b may be automatically generated (step S108), and the additional film formation recipe 32b may be executed (step S109).

Accordingly, film formation is additionally performed for a portion on which no film may be formed due to the abort, so that film replenishment may be performed, and then a desired film may be formed on the substrate. This may reduce substrates to be discarded. Also, it is possible to reduce the environmental load caused by the discarded substrates.

Also, since the optimization apparatus 3 automatically generates the additional film formation recipe 32b, it is possible to perform additional film formation on the substrate without engineers with a lot of experiences. Also, it is possible to reduce the risk of human setting errors (e.g., setting of gas type, and setting of time) when the additional film formation recipe 32b is generated. Also, since generation and execution of the additional film formation recipe 32b are performed with a single instruction from the operator, it is possible to reduce the burden on the operator.

The substrate processing system 1 may include a plurality of substrate processing apparatuses 2, and one optimization apparatus 3. Also, a substrate processing apparatus 2 (a first substrate processing apparatus) where the abort has occurred, and a substrate processing apparatus 2 (a second substrate processing apparatus) where additional film formation is performed may be different apparatuses. In this case, for a gray-state substrate discharged from the substrate processing apparatus 2 where the abort has occurred, the location of the substrate (transfer destination) may be tracked through, for example, an ID of a front opening unified pod (FOUP) that stores the substrate. The gray-state substrate is transported to another substrate processing apparatus 2 for performing the additional film formation (see, e.g., the step S107).

Also, the optimization apparatus 3 generates the additional film formation recipe 32b based on, for example, logs of the substrate processing apparatus 2 (the first substrate processing apparatus) where the abort has occurred (see, e.g., the step S108). Then, the optimization apparatus 3 transmits the additional film formation recipe 32b to the control device 20 of the other substrate processing apparatus 2 (the second substrate processing apparatus) for performing the additional film formation, via the communication unit 4. Then, the control device 20 of the other substrate processing apparatus 2 (the second substrate processing apparatus) controls the other substrate processing apparatus 2 according to the additional film formation recipe 32b for performing the additional film formation (see, e.g., the step S109). Then, the additional film formation recipe 32b stored in the ROM or the auxiliary storage device of the control device 20 of the other substrate processing apparatus 2 (the second substrate processing apparatus) is deleted. Also, the additional film formation recipe 32b is deleted from the storage unit 32 of the optimization apparatus 3. Accordingly, even in different apparatuses, the additional film formation may be performed on the gray-state substrate by using the additional film formation recipe 32b.

Also, although the optimization apparatus 3 has been described as being provided separately from the control device 20 of the substrate processing apparatus 2, the present disclosure is not limited to this configuration. The additional film formation recipe generation unit 31 and the storage unit 32 may be provided in the control device 20 of the substrate processing apparatus 2. Then, the substrate processing system 1 includes a plurality of substrate processing apparatuses 2, and the control device 20 of each substrate processing apparatus 2 is connected to the control device 20 of another substrate processing apparatus 2 via the communication unit 4.

In this configuration, the additional film formation recipe 32b is generated in the control device 20 of the substrate processing apparatus 2 (the first substrate processing apparatus) where the abort has occurred. Then, the additional film formation recipe 32b may be transmitted from the control device 20 of the substrate processing apparatus 2 (the first substrate processing apparatus) where the abort has occurred, to the control device 20 of the other substrate processing apparatus 2 (the second substrate processing apparatus) for performing the additional film formation. Then, the control device 20 of the other substrate processing apparatus 2 (the second substrate processing apparatus) controls the other substrate processing apparatus 2 according to the additional film formation recipe 32b for performing the additional film formation (see, e.g., the step S109). The additional film formation recipe 32b stored in the ROM or the auxiliary storage device of the control device 20 of the other substrate processing apparatus 2 (the second substrate processing apparatus) is deleted. Accordingly, even in different apparatuses, the additional film formation may be performed on the gray-state substrate by using the additional film formation recipe 32b.

Alternatively, for example, logs may be transmitted from the control device 20 of the substrate processing apparatus 2 (the first substrate processing apparatus) where the abort has occurred, to the control device 20 of the other substrate processing apparatus 2 (the second substrate processing apparatus) for performing the additional film formation, and then the additional film formation recipe 32b may be generated in the control device 20 of the other substrate processing apparatus 2 (the second substrate processing apparatus). Then, the control device 20 of the other substrate processing apparatus 2 (the second substrate processing apparatus) controls the other substrate processing apparatus 2 according to the additional film formation recipe 32b for performing the additional film formation (see, e.g., the step S109). The additional film formation recipe 32b stored in the ROM or the auxiliary storage device of the control device 20 of the other substrate processing apparatus 2 (the second substrate processing apparatus) is deleted. Accordingly, even in different apparatuses, the additional film formation may be performed on the gray-state substrate by using the additional film formation recipe 32b.

Also, in the configuration of the optimization apparatus 3, whether to discharge (unload) the gray-state substrate from the substrate processing apparatus 2 may be selected when an abort has occurred (S102; YES). The gray-state substrate may be left within the substrate processing apparatus 2 in the vacuum atmosphere, so that it is possible to prevent the substrate from being exposed to the air atmosphere and to prevent the surface state of the substrate from being changed (e.g., natural oxidation and moisture adsorption).

Also, it is desirable that the additional film formation recipe 32b is automatically deleted (step S110). This may prevent unnecessary recipes from remaining in the storage unit 32, and may prevent the operator from making a selection error, etc. when the process recipe 32a to be executed in the step S101 is selected before, for example, the execution of the step S101.

According to one aspect, it is possible to provide a method of controlling a substrate processing apparatus that performs additional film formation after a process recipe is aborted.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of controlling a substrate processing apparatus, the method comprising:
when an abort occurs in a substrate processing apparatus during a film forming processing on a substrate using a process recipe, generating an additional process recipe for the film forming processing according to a timing of the abort; and
performing an additional film forming processing on the substrate according to the additional process recipe.

2. The method according to claim 1, wherein the generating the additional process recipe includes storing the additional processing recipe in a storage, and
the method further comprises deleting the additional process recipe from the storage after performing the additional film forming processing.

3. The method according to claim 1, wherein the generating the additional process recipe includes:
determining a progressing degree of the process recipe as to how far the process recipe has progressed when the abort has occurred, by using at least one of logs of the substrate processing apparatus, a measurement result of an actual sensor in the substrate processing apparatus, a measurement result of a virtual sensor in the substrate processing apparatus, and measurement data of a substrate surface of the substrate, and
generating the additional process recipe based on a determination result of the progressing degree of the process recipe.

4. The method according to claim 1, further comprising:
determining whether an instruction has been input by an operator,
wherein when the instruction has been input, the generating the additional process recipe, and the performing the additional film forming process are executed.

5. The method according to claim 1, wherein the substrate processing apparatus includes a first substrate processing apparatus and a second substrate processing apparatus, and
the method further comprises:
when the abort occurs in the first processing apparatus during the film forming processing on the substrate using the process recipe, generating an additional process recipe according to a timing of the abort, by a first controller corresponding to the first substrate processing apparatus;
transferring the substrate processed in the first substrate processing apparatus, to the second substrate processing apparatus;
transmitting the additional process recipe from the first controller to a second controller corresponding to the second substrate processing apparatus; and
performing an additional film forming processing on the substrate according to the additional process recipe, in the second substrate processing apparatus.
